(19) United States
(12) Patent Application Publication
(10) Pub. No.: US 2016/0104856 A1
(43) Pub. Date: Apr. 14, 2016

(54) ORGANIC LIGHT-EMITTING ILLUMINATION APPARATUS

(71) Applicant: Samsung Display Co., Ltd., Yongin-city (KR)

(72) Inventor: Tsuyoshi Naijo, Yongin-city (KR)

(21) Appl. No.: 14/698,249

(22) Filed: Apr. 28, 2015

(30) Foreign Application Priority Data
Oct. 8, 2014 (KR) 10-2014-0135962

(51) Int. Cl. H01L 51/52; H01L 51/00

(52) U.S. Cl. CPC H01L 51/529; H01L 51/5218; H01L 51/5234; H01L 51/0097; H01L 51/5246

(57) ABSTRACT

An organic light-emitting illumination apparatus including: a first flexible substrate; a first electrode disposed on the first flexible substrate, the first electrode configured to reflect light in a first region of the first flexible substrate and transmit light in a second region of the first flexible substrate; an intermediate layer disposed on the first electrode, including a light emission layer; a second electrode disposed on the intermediate layer, configured to transmit light; a second flexible substrate disposed on the second electrode; a first heat dissipation layer disposed on the first flexible substrate, configured to transmit light, the first flexible substrate being disposed between the first heat dissipation layer and the first electrode; and a second heat dissipation layer disposed on the second flexible substrate, the second flexible substrate being disposed between the second heat dissipation layer and the second electrode, the second heat dissipation layer being configured to transmit light.

### CROSS-REFERENCE TO RELATED APPLICATION

This application claims priority from and the benefit of Korean Patent Application No. 10-2014-0135962, filed on Oct. 8, 2014, which is hereby incorporated by reference for all purposes as if fully set forth herein.

### BACKGROUND

1. Field

Exemplary embodiments relate to organic light-emitting illumination apparatuses, and, more particularly, to organic light-emitting illumination apparatuses configured to dissipate heat while achieving relatively high-levels of brightness.

2. Discussion of the Background

In general, an organic light-emitting device may be used as a display device of an organic light-emitting display apparatus. It is noted, however, that light generated by organic light-emitting devices is generally insufficient for illumination in a display device, unless a relatively strong electrical signal is applied to the organic light-emitting device. Applying relatively strong electrical signals to the organic light-emitting device may produce excessive heat, which may result in reducing the lifetime of the organic light-emitting device.

The above information disclosed in this Background section is only for enhancement of understanding of the background of the inventive concept, and, therefore, it may contain information that does not form any part of the prior art nor what the prior art may suggest to a person of ordinary skill in the art.

### SUMMARY

Exemplary embodiments provide organic light-emitting illumination apparatuses configured to dissipate heat while achieving relatively high-levels of brightness.

Additional aspects will be set forth in the detailed description which follows, and, in part, will be apparent from the disclosure, or may be learned by practice of the inventive concept.

According to one or more exemplary embodiments, an organic light-emitting illumination apparatus includes: a first flexible substrate; a first electrode disposed on the first flexible substrate, the first electrode configured to reflect light in a first region of the first flexible substrate and transmit light in a second region of the first flexible substrate; an intermediate layer disposed on the first electrode, the intermediate layer including a light emission layer; a second electrode disposed on the intermediate layer, the second electrode being configured to transmit light; a second flexible substrate disposed on the second electrode; a first heat dissipation layer disposed on the first flexible substrate, the first flexible substrate being disposed between the first heat dissipation layer and the first electrode, the first heat dissipation layer being configured to transmit light; and a second heat dissipation layer disposed on the second flexible substrate, the second flexible substrate being disposed between the second heat dissipation layer and the second electrode, the second heat dissipation layer being configured to transmit light.

The foregoing general description and the following detailed description are exemplary and explanatory and are intended to provide further explanation of the claimed subject matter.

### BRIEF DESCRIPTION OF THE DRAWINGS

The accompanying drawings, which are included to provide a further understanding of the inventive concept, and are incorporated in and constitute a part of this specification, illustrate exemplary embodiments of the inventive concept, and, together with the description, serve to explain principles of the inventive concept.

FIG. 1 is a cross-sectional view schematically illustrating an organic light-emitting illumination apparatus, according to one or more exemplary embodiments.

FIG. 2 is a cross-sectional view schematically illustrating use of the organic light-emitting illumination apparatus of FIG. 1, according to one or more exemplary embodiments.

FIG. 3 is a cross-sectional view schematically illustrating an organic light-emitting illumination apparatus, according to one or more exemplary embodiments.

### DETAILED DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. Like numbers refer to like elements throughout. As used herein, the term “and/or” includes any and all combinations of one or more of the associated listed items.

Although the terms first, second, etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various exemplary embodiments are described herein with reference to sectional illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

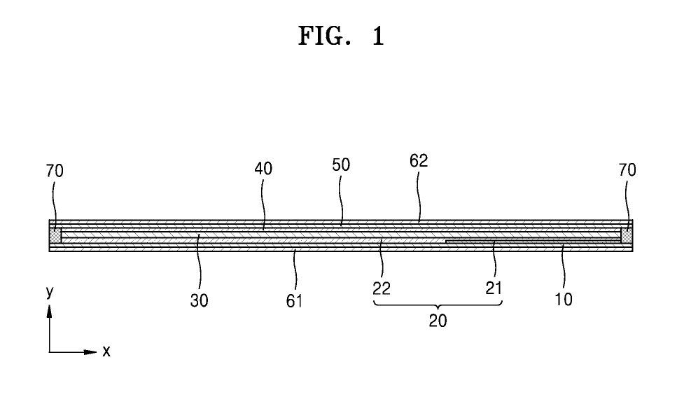

FIG. 1 is a cross-sectional view schematically illustrating an organic light-emitting illumination apparatus, according to one or more exemplary embodiments.

As illustrated in FIG. 1, the organic light-emitting illumination apparatus may include a first flexible substrate 10, a first electrode 20, an intermediate layer 30, a second electrode 40, a second flexible substrate 50, a first heat dissipation layer 61, and a second heat dissipation layer 62.

The first flexible substrate 10 is flexible and may transmit light. The first flexible substrate 10 may include a polymer material, for example, polyimide. The second flexible substrate 50 may include the same material as the first flexible substrate 10. The first flexible substrate 10 and the second flexible substrate 50 may each have a multilayer structure and various modified structures, such as an alternate stack structure of inorganic layers and organic layers. Also, the first flexible substrate 10 and the second flexible substrate 50 may each have a shape of a film.

The first electrode 20 is disposed on the first flexible substrate 10. A buffer layer (not shown) may be further interposed between the first flexible substrate 10 and the first electrode 20. The first electrode 20 may reflect light in a first region and may transmit light in a second region, wherein the second region is a remaining region other than the first region. The first electrode 20 may have various configurations. For example, the first electrode 20 may include a reflective electrode 21 located in the first region and a transparent electrode 22 located in the second region. The transparent electrode 22 may be located only in the second region, or may be located in both of the first region and the second region as illustrated in FIG. 1. FIG. 1 illustrates that the transparent electrode 22 covers the reflective electrode 21 in the first region.

The reflective electrode 21 may be formed of at least one of argentum (Ag), magnesium (Mg), aluminum (Al), platinum (Pt), palladium (Pd), aurum (Au), nickel (Ni), neodymium (Nd), iridium (Ir), chromium (Cr), lithium (Li), calcium (Ci), lithium fluoride (LiF)/Ca, and LiF/Al. The transparent electrode 22 may be formed of at least one of a transparent electrode material such as indium tin oxide (ITO), indium zinc oxide (IZO), zinc oxide (ZnO), and indium oxide (In₂O₃).

The second electrode 40 is disposed on a surface of the second flexible substrate 50 facing the first flexible substrate 10. The second electrode 40 may be formed of a material capable of transmitting light. The second electrode 40 may also be formed of a transparent electrode material such as ITO, IZO, ZnO, and/or In₂O₃.

The intermediate layer 30 is interposed between the first electrode 20 and the second electrode 40. The intermediate layer 30 may include at least a light emission layer, and may be formed of a low-molecular organic material and/or a high-molecular organic material.

When the intermediate layer 30 is formed of a low-molecular organic material, the intermediate layer 30 may have a stack structure of a hole injection layer (HIL), a hole transport layer (HTL), an organic emission layer (EML), an electron transport layer (ETL), and an electron injection layer (EIL). In this case, the intermediate layer 30 may include an organic material such as copper phthalocyanine (CuPc), N,N′-Di(naphthalene-1-yl)-N,N′-diphenyl-benzidine (NPB), and/or tris-8-hydroxyquinoline aluminum (Alq3). The intermediate layer 30 including a low-molecular organic material may be formed by vacuum deposition using masks.

When the intermediate layer 30 is formed of a high-molecular organic material, the intermediate layer 30 may include a hole transport layer and an organic emission layer. In this case, poly-3,4-ethylendioxythiophene (PEDOT) may be used for the hole transport layer, and a high-molecular organic material such as poly-phenylenevinylene (PPV) and/or polyfluorene may be used for the organic emission layer.

The organic emission layer included in the intermediate layer 30 may emit white light, or may include a red emission layer emitting red light, a green emission layer emitting green light, and a blue emission layer emitting blue light.

The first heat dissipation layer 61 is disposed on the first flexible substrate 10, the first flexible substrate 10 being disposed between the first heat dissipation layer 61 and the first electrode 20. The second heat dissipation layer 62 is disposed on the second flexible substrate 50, the second flexible substrate 50 being disposed between the second heat dissipation layer 62 and the second electrode 40. That is, the first heat dissipation layer 61 and the second heat dissipation layer 62 are disposed on the outer surfaces of the first flexible substrate 10 and the second flexible substrate 50, enclosing the intermediate layer 30. The first heat dissipation layer 61 and the second heat dissipation layer 62 may be formed of a material capable of transmitting light, having high heat dissipation performance. For example, the first heat dissipation layer 61 and/or the second heat dissipation layer 62 may include graphene, which is transparent and has high heat dissipation performance. The first heat dissipation layer 61 and/or the second heat dissipation layer 62 may also be formed by depositing and curing liquid heat-dissipative transparent paint, which may be a mixture of powder of ceramic material and resin. For example, the first heat dissipation layer 61 and/or the second heat dissipation layer 62 may be formed of liquid heat-dissipative transparent paint, which is a mixture of mixing powder of hydrotalcite series compound and acryl resin, polyolefin resin, and/or cellulose acetate resin.

To protect the intermediate layer 30 from impurities such as external moisture and/or oxygen, the organic light-emitting illumination apparatus may include a sealant 70 that is interposed between the first flexible substrate 10 and the second flexible substrate 50 along edges thereof to enclose the intermediate layer 30, as illustrated in FIG. 1.

Exemplary embodiments are not limited to the illustration of FIG. 1. For example, at least a portion of the first electrode 20 and/or the second electrode 40 may extend outside the sealant 70 so that an electrical signal may be applied to the first electrode 20 and/or the second electrode 40. Also, the organic light-emitting illumination apparatus may not include the sealant 70, but instead, the first flexible substrate 10 and the second flexible substrate 50 may further extend and contact each other, enclosing the intermediate layer 30.

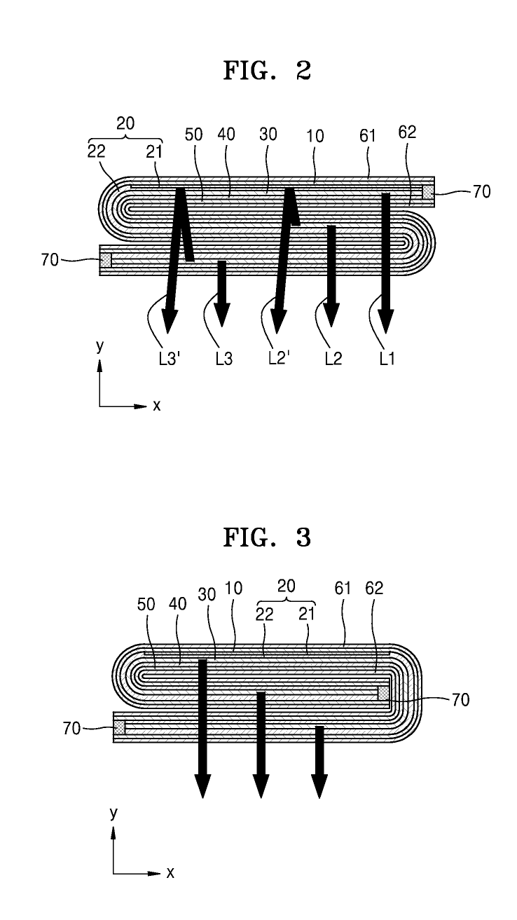

The organic light-emitting illumination apparatus may have various usages. For example, the organic light-emitting illumination apparatus may be used in an unfolded state as illustrated in FIG. 1, or may be used in a folded state where the illumination apparatus is bent a plurality of times as illustrated in FIG. 2. When the organic light-emitting illumination apparatus is used in unfolded state as illustrated in FIG. 1, light is emitted in a direction from the reflective electrode 21 toward the second flexible substrate 50 (+y direction) in the first region of the first electrode 20 corresponding to the reflective electrode 21. That is, in the first region of the first electrode 20 corresponding to the reflective electrode 21, light generated from the intermediate layer 30 is emitted outside through the second flexible substrate 50. In the second area of the first electrode 20, light generated at the intermediate layer 30 is emitted outside through both the first flexible substrate 10 and the second flexible substrate 50. Thus, the organic light-emitting illumination apparatus may be used in an unfolded state as illustrated in FIG. 1 to illuminate only one side in the first region of the first electrode 20 including the reflective electrode 21, and illuminate both sides in the second region of the first electrode 20.

To provide illumination for emitting high-brightness light in a particular direction, the organic light-emitting illumination apparatus may be used in a folded state as illustrated in FIG. 2. For instance, the first flexible substrate 10 and the second flexible substrate 50 may be bent and folded a plurality of times to provide a light emission area corresponding to the reflective electrode 21 of the first electrode 20. In this case, one edge (in +x direction) of the reflective electrode 21 of the first electrode 20 is located at one edge (in +x direction) of the first flexible substrate 10 as illustrated in FIG. 1, so the organic light-emitting illumination apparatus corresponding to the first region of the reflective electrode 21 may be implemented by folding organic light-emitting illumination apparatus so that the first flexible substrate 10 corresponding to the reflective electrode 21 is not disposed between the first flexible substrate 10 and the portion of the first flexible substrate 10 and the second flexible substrate 50 in the second region as illustrated in FIG. 2.

As illustrated in FIG. 2, a light L1 generated from the intermediate layer 30 corresponding to the reflective electrode 21 including the light emission layer is emitted (in −y direction) through the portion of the first flexible substrate 10 not corresponding to the reflective electrode 21 and the second flexible substrate 50. In this process, the light L1 is emitted outside after penetrating the second flexible substrate 50 a plurality of times. Depending on the number of times of folding the organic light-emitting illumination apparatus, the light L1 may also penetrate the first flexible substrate 10 a plurality of times.

Lights L2, L2′, L3, and L3′ are generated and emitted from the second region not corresponding to the reflective electrode 21 of the intermediate layer 30 including the light emission layer. The lights L2 and L3 propagate directly in the same direction (−y direction) as the light L1 and are emitted outside. The lights L2′ and L3′ propagate in the direction (+y direction) toward the reflective electrode 21, are reflected by the reflective electrode 21, propagate in the same direction (−y direction) as the light L1, and are emitted outside.

According to exemplary embodiments, when the first flexible substrate 10 and the second flexible substrate 50 are bent and folded a plurality of times to provide a light emission area corresponding to the reflective electrode 21 of the first electrode 20 as illustrated in FIG. 2, all the lights L1, L2, L2′, L3, and L3′ may propagate in the same direction (−y direction), and the organic light-emitting illumination apparatus may have improved and relatively high brightness. In this case, the strength of an electrical signal is not increased to sufficiently brighten the light, but the first flexible substrate 10 and the second flexible substrate 50 are simply bent and folded a plurality of times, the reduction of the lifetime of an organic light-emitting device may be effectively prevented or reduced.

When the organic light-emitting illumination apparatus is used in a folded state as illustrated in FIG. 2, it is necessary to perform proper heat dissipation between folded portions. The organic light-emitting device is vulnerable to heat, and, therefore, heat generated at light emission needs to be quickly dissipated to the surrounding environment. In particular, when the organic light-emitting illumination apparatus is used in a partially folded state as illustrated in FIG. 2, the heat generated in the folded area should be sufficiently dissipated.

In the case of the organic light-emitting illumination apparatus according to the exemplary embodiment, the first heat dissipation layer 61 and the second heat dissipation layer 62, which are transparent, are located on the first flexible substrate 10 and the second flexible substrate 50 as described above. Thus, even when the organic light-emitting illumination apparatus is used in a folded state as illustrated in FIG. 2, heat generated at a folded portion may be transferred along the first heat dissipation layer 61 and the second heat dissipation layer 62. That is, the first heat dissipation layer 61 and the second heat dissipation layer 62 function as a heat transfer path from the folded portion of the organic light-emitting illumination apparatus to portions of the first heat dissipation layer 61 and the second heat dissipation layer 62 that are adjacent to the surrounding environment, and thus heat may be effectively dissipated to the surrounding environment through the portions of the first heat dissipation layer 61 and the second heat dissipation layer 62 that are adjacent to the surrounding environment. The first heat dissipation layer 61 covers an entirety of a surface of the first flexible substrate 10 upon which the first heat dissipation layer 61 is disposed, and the second heat dissipation layer 62 covers an entirety of a surface of the second flexible substrate 50 upon which the second heat dissipation layer 62 is disposed.

Although FIGS. 1 and 2 illustrate that one edge of the reflective electrode 21 of the first electrode 20 is located adjacent to one edge of the first flexible substrate 10, exemplary embodiments are not limited thereto. Referring to FIG. 3, the reflective electrode 21 may be located at a center portion of the first flexible substrate 10. In this case, the organic light-emitting illumination apparatus may be used in the folded mode by folding the regions of the organic light-emitting illumination apparatus that does not correspond to the reflective electrode 21, onto the portion of the first flexible substrate 10 corresponding to the reflective electrode 21. Therefore, the organic light-emitting illumination apparatus may be used to emit high-brightness light.

As described above, according to the one or more of the exemplary embodiments, it is possible to implement an organic light-emitting illumination apparatus that may effectively dissipate heat while achieving high-brightness illumination.

Although certain exemplary embodiments and implementations have been described herein, other embodiments and modifications will be apparent from this description. Accordingly, the inventive concept is not limited to such embodiments, but rather to the broader scope of the presented claims and various obvious modifications and equivalent arrangements.

What is claimed is:

1. An organic light-emitting illumination apparatus comprising:
a first flexible substrate;
a first electrode disposed on the first flexible substrate, the first electrode configured to reflect light in a first region of the first flexible substrate and transmit light in a second region of the first flexible substrate;
an intermediate layer disposed on the first electrode, the intermediate layer comprising a light emission layer;
a second electrode disposed on the intermediate layer, the second electrode being configured to transmit light;
a second flexible substrate disposed on the second electrode;
a first heat dissipation layer disposed on the first flexible substrate, the first flexible substrate being disposed between the first heat dissipation layer and the first electrode, the first heat dissipation layer being configured to transmit light; and
a second heat dissipation layer disposed on the second flexible substrate, the second flexible substrate being disposed between the second heat dissipation layer and the second electrode, the second heat dissipation layer being configured to transmit light.

2. The organic light-emitting illumination apparatus of claim 1, wherein:
the first heat dissipation layer covers an entirety of a surface of the first flexible substrate upon which the first heat dissipation layer is disposed; and
the second heat dissipation layer covers an entirety of a surface of the second flexible substrate upon which the second heat dissipation layer is disposed.

3. The organic light-emitting illumination apparatus of claim 1, wherein the first electrode comprises:
a reflective electrode disposed in the first region; and
a transparent electrode disposed in the second region.

4. The organic light-emitting illumination apparatus of claim 3, wherein, in a bent and folded state, the first flexible substrate and the second flexible substrate are bent and folded a plurality of times to provide a light emission area corresponding to the reflective electrode.

5. The organic light-emitting illumination apparatus of claim 4, wherein:
the reflective electrode is disposed on a portion of the first flexible substrate; and
in the bent and folded state, the portion of the first flexible substrate is not covered by the second flexible substrate and another portion of the first flexible substrate disposed adjacent to the portion of the first flexible substrate in a non-bent and non-folded state of the first flexible substrate.

6. The organic light-emitting illumination apparatus of claim 3, wherein an edge of the reflective electrode is adjacent to an edge of the first flexible substrate.

7. The organic light-emitting illumination apparatus of claim 1, wherein the first electrode comprises:
a reflective electrode disposed in the first region; and
a transparent electrode overlapping the first region and the second region.

8. The organic light-emitting illumination apparatus of claim 7, wherein, in a bent and folded state, the first flexible substrate and the second flexible substrate are bent and folded a plurality of times to provide a light emission area corresponding to the reflective electrode.

9. The organic light-emitting illumination apparatus of claim 8, wherein:
the reflective electrode is disposed on a portion of the first flexible substrate; and
in the bent and folded state, the portion of the first flexible substrate is not covered by the second flexible substrate and another portion of the first flexible substrate disposed adjacent to the portion of the first flexible substrate in a non-bent and non-folded state of the first flexible substrate.

10. The organic light-emitting illumination apparatus of claim 7, wherein an edge of the reflective electrode is disposed adjacent to an edge of the first flexible substrate.

11. The organic light-emitting illumination apparatus of claim 7, wherein the reflective electrode is centrally disposed on the first flexible substrate.

12. The organic light-emitting illumination apparatus of claim 11, wherein, in a bent and folded state, the first flexible substrate and the second flexible substrate are bent and folded a plurality of times to provide a light emission area corresponding to the reflective electrode.

13. The organic light-emitting illumination apparatus of claim 12, wherein:
the reflective electrode is disposed on a first portion of the first flexible substrate;
a second portion of the first flexible substrate is disposed adjacent to a first side of the first portion of the first flexible substrate in a non-bent and non-folded state of the first flexible substrate;
a third portion of the first flexible substrate is disposed adjacent to a second side of the first portion of the first flexible substrate in a non-bent and non-folded state of the first flexible substrate; and
in the bent and folded state, the first portion of the first flexible substrate is not covered by the second and third portions of the first flexible substrate.

14. The organic light-emitting illumination apparatus of claim 1, wherein the second region is a remaining region of the first flexible substrate.

15. The organic light-emitting illumination apparatus of claim 1, further comprising:
a sealant coupling the first flexible substrate to the second flexible substrate,
wherein the sealant encloses the intermediate layer between the first flexible substrate and the second flexible substrate.

16. The organic light-emitting illumination apparatus of claim 15, wherein the sealant is disposed along edges of the first flexible substrate and the second flexible substrate.

17. The organic light-emitting illumination apparatus of claim 5, wherein, in the bent and folded state, light emitted in a first direction by underlying folds of the light emission layer is reflected by the reflective layer to increase light radiation in a second direction opposite the first direction.

18. The organic light-emitting illumination apparatus of claim 9, wherein, in the bent and folded state, light emitted in a first direction by underlying folds of the light emission layer is reflected by the reflective layer to increase light radiation in a second direction opposite the first direction.

19. The organic light-emitting illumination apparatus of claim 12, wherein, in the bent and folded state, light emitted in a first direction by underlying folds of the light emission layer is reflected by the reflective layer to increase light radiation in a second direction opposite the first direction.
